(19) United States
(12) Patent Application Publication
(10) Pub. No.: US 2025/0365940 A1
(43) Pub. Date: Nov. 27, 2025

(54) METHOD OF FORMING SEMICONDUCTOR STRUCTURE

(71) Applicant: NANYA TECHNOLOGY CORPORATION, New Taipei City (TW)

(72) Inventor: Jung Tzu PENG, New Taipei City (TW)

(21) Appl. No.: 18/674,906

(22) Filed: May 26, 2024

(51) Int. Cl. H10B 12/00

(52) U.S. Cl. CPC H10B 12/482; H10B 12/0335; H10B 12/488

(57) ABSTRACT

A method of forming a semiconductor structures includes forming a hard mask layer on a substrate, forming a plurality of word line trenches in the substrate and the hard mask layer, forming a plurality of word line structures in the word line trenches. A top surface of the word line structures and the substrate are coplanar. The method further includes forming a first dielectric layer in the word line trenches. A top surface of the first dielectric layer is coplanar with a top surface of the hard mask layer. The method further includes removing the hard mask layer to define a plurality of trenches in the first dielectric layer, forming a sacrificial layer in the trenches, forming a plurality of bit line trenches in the sacrificial layer and the first dielectric layer, and forming a plurality of bit line structure in the bit line trenches.

### BACKGROUND

### Field of Invention

The present invention relates to method of forming semiconductor structure. More particularly, the present invention relates to the improvement of the fabricating process of semiconductor structure.

### Description of Related Art

The dimension of the memory device continues to scale down for the demand of larger storage capability of the memory device, so that the density of the memory device has been increasing. For increasing the storage capability of the memory device (e.g., the dynamic random access memory (DRAM) device), the semiconductor structures are arranged in the memory device, and each of the semiconductor structures becomes a smaller size.

The semiconductor structures are fabricated on an active area, which is a portion of a semiconductor substrate. The active area includes a capacitor contact area located at two end portion of the active area. Each of the semiconductor structures can include a storage capacitor connected to the capacitor contact area of the active area through a capacitor contact. With the shrinkage size of the semiconductor structure, it becomes more difficult to control the area of the capacitor contact area. Smaller area of the capacitor contact area will increase the contact resistance of the capacitor contact. Therefore, a method of improving the accuracy of the fabrication without influencing the area of the capacitor contact area in the art is important.

### SUMMARY

The invention provides a method of forming the semiconductor structures. The method includes forming a hard mask layer on a substrate, forming a plurality of word line trenches in the substrate and the hard mask layer, forming a plurality of word line structures in the word line trenches. A top surface of the word line structures is coplanar with a top surface of the substrate. The method further includes forming a first dielectric layer in the word line trenches and extending upward from the substrate. A top surface of the first dielectric layer is coplanar with a top surface of the hard mask layer. The method further includes removing the hard mask layer to define a plurality of trenches in the first dielectric layer, forming a sacrificial layer in the trenches, forming a plurality of bit line trenches in the sacrificial layer and the first dielectric layer, forming a plurality of bit line structure in the bit line trenches.

The invention provides a method of forming the semiconductor structures. The method includes forming a plurality of word line structures in a substrate, forming a first dielectric layer on the substrate. The first dielectric layer vertical aligns with the word line structures. The method further includes depositing a sacrificial layer on the substrate, forming a plurality of bit line structures in the sacrificial layer. The first dielectric layer extends in a first direction, and the bit line structures extend in a second direction vertical to the first direction. The method further includes removing the sacrificial layer and forming a plurality of capacitor contacts on the substrate. The location of capacitor contacts defined by first dielectric layer and the bit line structures.

These and other features, aspects, and advantages of the present invention will become better understood with reference to the following description and appended claims.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a semiconductor structure according to some embodiments of the present disclosure.

FIGS. 2, 5, 10, 16, 19, 24, 26 are top views of a method of forming a semiconductor structure at different stages according to some embodiments of the present disclosure.

FIGS. 3-4, 6-9, 11-15, 17-18, 20-23, 25, 27-29 are cross-section views of a method of forming a semiconductor at different stages according to some embodiments of the present disclosure.

### DETAILED DESCRIPTION

Reference will now be made in detail to the present embodiments of the invention, examples of which are illustrated in the accompanying drawings.

Wherever possible, the same reference numbers are used in the drawings and the description to refer to the same or like parts.

It will be understood that, although the terms “first”, “second”, “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Furthermore, relative terms, such as “lower” or “bottom” and “upper” or “top”, may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper”, depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

As used herein, “around”, “about” or “approximately” shall generally mean within 20 percent, preferably within 10 percent, and more preferably within 5 percent of a given value or range. Numerical quantities given herein are approximate, meaning that the term “around”, “about” or “approximately” can be inferred if not expressly stated.

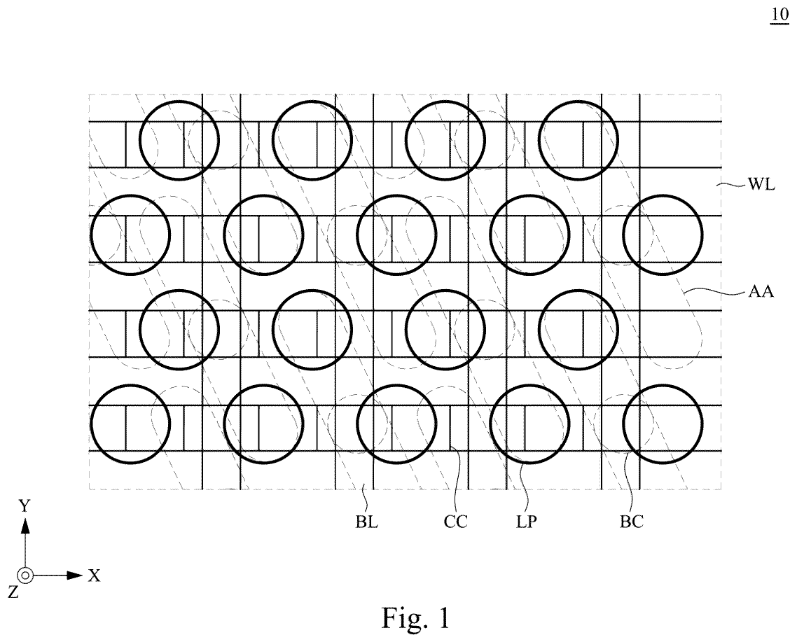

Referring to FIG. 1, FIG. 1 is a top view of some embodiments of the semiconductor structure 10, in accordance with the present disclosure. The semiconductor structure 10 may include plurality of active areas AA, wherein each of the plurality of the active areas AA includes a short axis and a long axis. In some embodiments, the long axis of the active areas AA may extend in a diagonal axis with respect to a X axis.

A plurality of word line structures WL are across a portion of the plurality of the active areas AA and extend along a Y axis. Adjacent word line structures WL are spaced apart from each other in a constant distant and parallel to each other. A plurality of bit line structures BL are disposed on the plurality of the word line structures WL and extend along the X axis. Adjacent bit line structures BL are spaced apart from each other in a constant distant as well. In addition, the plurality of the bit line structures BL may connect to the plurality of the active areas AA by a plurality of bit line contacts BC. Each of the plurality of the active areas AA may electrically connect to a bit line contact BC.

A plurality of capacitor contacts CC are disposed between the adjacent plurality of the bit line structures BL. In some embodiments, the plurality of the bit line contacts BC are spaced apart from each other in X axis direction. The plurality of the capacitor contacts CC may electrically connect bottom electrodes of the capacitors (not shown) to the related active areas AA. Each of the plurality of the active areas may electrically connect two capacitor contacts CC.

A plurality of landing pads LP are disposed on the plurality of the capacitor contacts CC and overlying a portion of the plurality of the bit line structures BL. The plurality of the landing pads LP may electrically connect to the plurality of the capacitor contacts CC, and electrically connect bottom electrodes of the capacitors (not shown) to the related active areas AA. In other words, the capacitors (not shown) may connect to the related active areas AA through the plurality of the capacitor contacts CC and the related plurality of the landing pads LP.

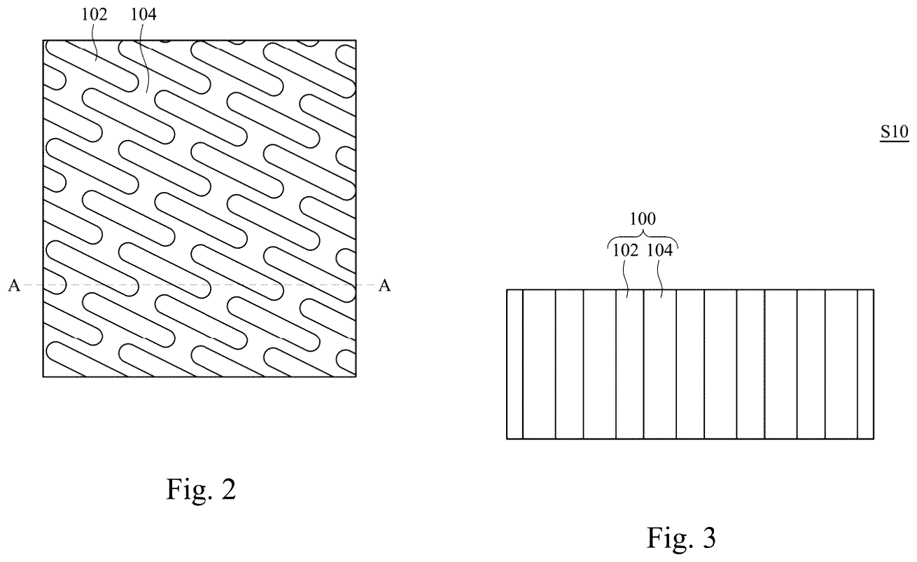

Reference is made to FIG. 2 to FIG. 29, which are top views and cross-sectional views of a method of forming a semiconductor structure at different stages according to some embodiments of the present disclosure.

Referring to FIG. 2 and FIG. 3, FIG. 2 is a top view of a stage of the method of forming the semiconductor structure according to some embodiments of the present disclosure, and FIG. 3 is a cross-section view of the semiconductor structure across the plane A-A shown in FIG. 2. The method begins from step S10. A substrate 100 is provided. The substrate 100 includes a plurality of active areas 102 and isolation area 104. The plurality of the active areas 102 are spaced apart from each other by the isolation area 104. In some embodiments, the isolation area 104 may include oxide, and the isolation area 104 may be considered as shallow trench isolation (STI). Each of the plurality of the active areas 102 has a short axis and a long axis. In some embodiment, the long axis of the active areas 102 may extend in a diagonal axis with respect to the X axis. The plurality of the active areas 102 are isolated from each other by the isolation area 104 with reference to FIG. 2.

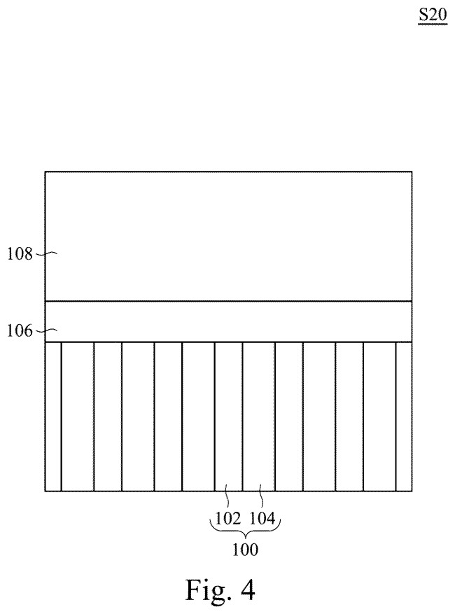

Refer to FIG. 4. FIG. 4 is a cross-section view of a stage of the method of forming the semiconductor structure according to some embodiments of the present disclosure, in which the cross-section of FIG. 4 is taken as the plane A-A shown in FIG. 2. The method goes to step S20, an isolation layer 106 is formed on a top surface of the plurality of the active areas 102 and the isolation area 104, followed by deposition of a first hard mask layer 108 on the isolation layer 106. In some embodiments, the first hard mask layer 108 may have a required thickness to form bit line structures following formed. In some embodiments, the height of the first hard mask layer 108 is equivalent to the height of the bit line structures.

In some embodiments, the isolation layer 106 may be any suitable dielectric material, such as silicon oxide, silicon nitride, silicon oxynitride, tetraethylorthosilicate (TEOS) oxide, un-doped silicate glass (USG), borophosphosilicate glass (BPSG), fluorinated silicate glass (FSG), phosphosilicate glass (PSG), borosilicate glass (BSG), another suitable material, or a combination thereof.

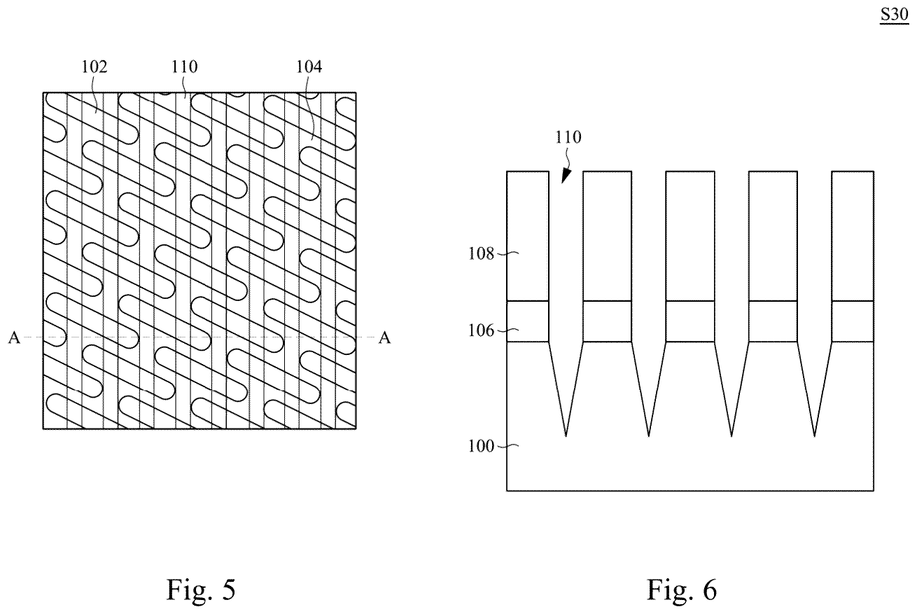

Referring to FIG. 5 and FIG. 6, FIG. 5 is a top view of a stage of the method of forming the semiconductor structure according to some embodiments of the present disclosure, and FIG. 6 is a cross-section view of the semiconductor structure across the plane A-A shown in FIG. 5. The method goes to step S30. The substrate 100, the isolation layer 106 and the first hard mask layer 108 may be patterned to form a plurality of word line trenches 110. The formation of the plurality of the word line trenches may use any suitable etch operations, such as an anisotropic dry etch process.

The plurality of the word line trenches 110 extend from the top surface of the first hard mask layer 108 through the isolation layer 106 and expose the substrate 100. In some embodiments, a portion of the plurality of the word line trenches 110 in the isolation layer 106 and the first hard mask layer 108 may have a consistent width, and a portion of the plurality of the word line trenches 110 in the substrate 100 may be a concave shape.

In accordance with FIG. 5, the plurality of the word line trenches 110 are formed in line along the plane vertical to the plane A-A and through a portion of the plurality of the active areas 102. Each of the plurality of the active areas 102 may be through by the adjacent plurality of the word line trenches 110.

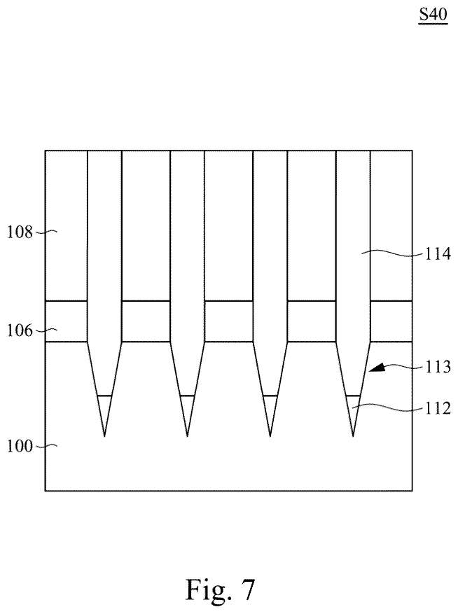

Referring to FIG. 7. FIG. 7 is a cross-section view of a stage of the method of forming the semiconductor structure according to some embodiments of the present disclosure, in which the cross-section of FIG. 7 is taken as the plane A-A shown in FIG. 5. The method goes to step S40. A first conductive layer 112 is formed in bottom sections of the plurality of the word line trenches 110, followed by the formation of a first dielectric layer 114 over the first conductive layer 112. The first conductive layer 112 may be formed by depositing conductive material in the plurality of the word line trenches 110, and removing a portion of the conductive material on a top surface of the first hard mask layer 108 and in top sections of the plurality of the word line trenches 110. A top surface of the first conductive layer 112 may be lower than a bottom surface of the isolation layer 106. The remaining conductive material may be at the bottom sections of the plurality of the word line trenches 110 as the first conductive layer 112. Following formation of the first conductive layer 112, the first dielectric layer 114 is deposited on the first conductive layer 112 and fills the word line trenches 110. Then, remove the first dielectric layer 114 above the top surface of the first hard mask layer 108. In some embodiments, the top surface of the first hard mask layer 108 and the first dielectric layer 114 may be coplanar.

The first conductive layer 112 may be deposited by any suitable deposition operation, such as a chemical vapor deposition (CVD), physical vapor deposition (PVD), atomic layer deposition (ALD), e-beam evaporation, or the like. The material of the first conductive layer 112 may use any suitable materials, such as tungsten, copper, tantalum, molybdenum, titanium, titanium nitride, tantalum nitride, or the like. The first conductive layer 112 may be a single layer, or multi layers. The first conductive layer 112 may be removed by any suitable operation, such as reactive ion etching (RIE), wet etching, plasma etching, inductively coupled plasma (ICP) etching, or the like. In some embodiments, the material of the first dielectric layer 114 may include silicon nitride. The first dielectric layer 114 may be removed by a chemical mechanical planarization (CMP), anisotropic etch, combination thereof, or the like.

The portions of the first dielectric layer 114 in the word line trenches 110 can be referred as cap layers of word line structures 113, and the first conductive layer 112 in the word line trenches 110 can be referred as conductive layers of the word line structures 113. In some embodiments, a top surface of the word line structures is coplanar with a top surface of the substrate. The embodiments of the present disclosure provide a method of simultaneously forming the plurality of the word line structures 113 and the first dielectric layer 114 in one mask. In some embodiments, side walls of the word line structures 113 vertical aligns side walls of the first dielectric layer 114. The top portion of the first dielectric layer 114 extending upward the substrate 100, in which the first dielectric layer 114 may further define the capacitor contact area on the substrate 100 following formed. If the plurality of the word line structures 113 and the first dielectric layer 114 are formed respectively with two masks, the aligning problem is present, which may reduce the area of the capacitor contact area. Besides, extra indie OVL measurement and control are necessary.

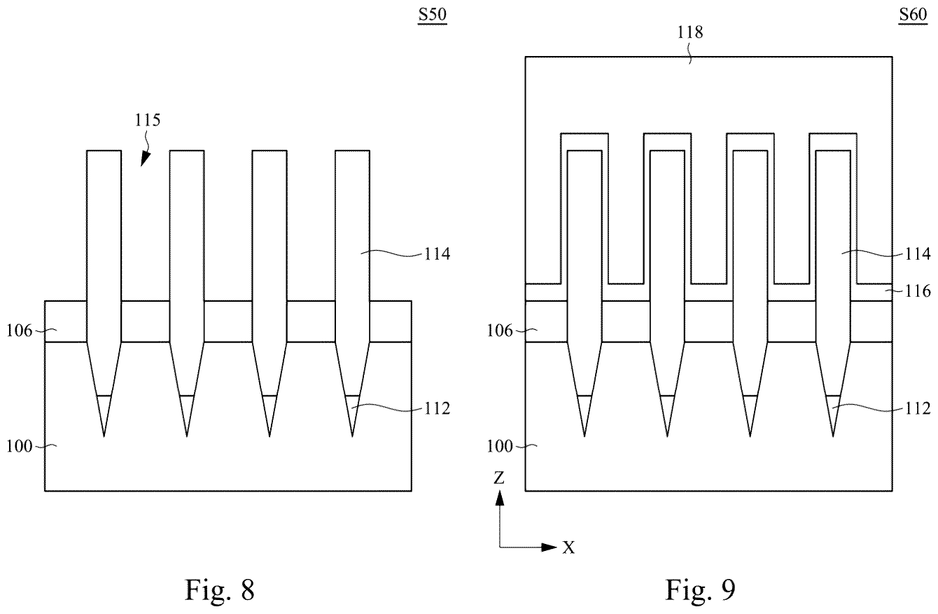

Referring to FIG. 8. FIG. 8 is a cross-section view of a stage of the method of forming the semiconductor structure according to some embodiments of the present disclosure, in which the cross-section of FIG. 8 is taken as the plane A-A shown in FIG. 5. The method goes to step S50. The first hard mask layer 108 is removed, leaving the first dielectric layer 114 in a linear structure along the plane vertical to the plane A-A on the substrate. After removal of the first hard mask layer 108, a plurality of trenches 115 is formed between the first dielectric layer 114. In some embodiments, the removal of the first hard mask layer 108 may include RIE, ICP, wet etching or another suitable etch operation.

Referring to FIG. 9. FIG. 9 is a cross-section view of a stage of the method of forming the semiconductor structure according to some embodiments of the present disclosure, in which the cross-section of FIG. 9 is taken as the plane A-A shown in FIG. 5. The method goes to step S60. A second dielectric layer 116 is formed on the first dielectric layer 114 and filling the trench 115 between the first dielectric layer 114, followed by formation of a second hard mask layer 118. The second dielectric layer 116 can control critical dimension (CD) along the X axis of a plurality of bit line contacts (not shown) following formed. In some embodiments, the second dielectric layer 116 may be blanket deposited as a conformal layer on the first dielectric layer 114. The second dielectric layer 116 may be deposited by any suitable deposition operation, such as CVD, PVD, ALD, low-pressure CVD (LPCVD), plasma-enhanced chemical vapor deposition (PECVD), e-beam evaporation, MBE or the like. The second hard mask layer 118 fills the trenches 115 between the first dielectric layer 114, and the second hard mask layer 118 further covers the first dielectric layer 114.

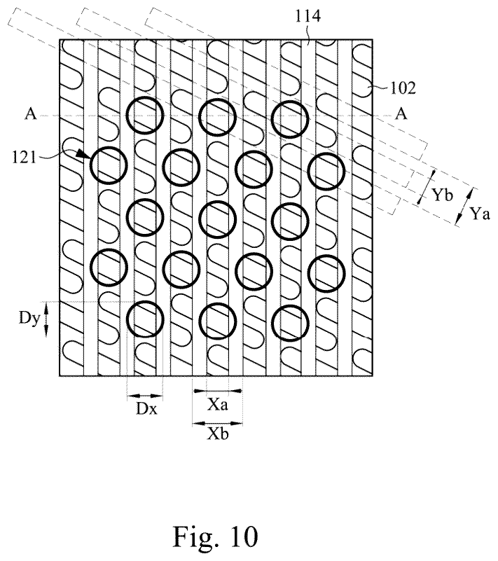

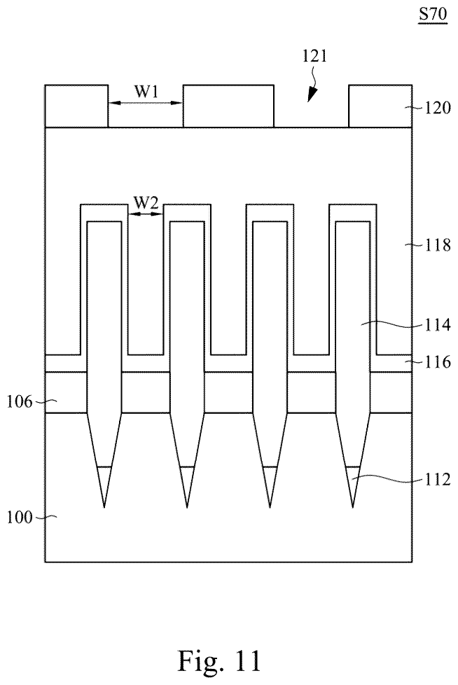

Referring to FIG. 10 and FIG. 11, FIG. 10 is a top view of a stage of the method of forming the semiconductor structure according to some embodiments of the present disclosure, and FIG. 11 is a cross-section view of the semiconductor structure across the plane A-A shown in FIG. 10. The method goes to step S70. A first photoresist layer is formed on the second hard mask layer 118, then patterning the first photoresist layer to form patterned first photoresist 120. The patterned first photoresist 120 may have openings 121 between the first dielectric layers 114, for defining the location of a plurality of the bit line contact holes (not shown). A width W1 of the opening 121 may be larger than a width W2 of the trenches between the first dielectric layer 114 and the second dielectric layer 116.

The patterned first photoresist 120 may have the openings 121 exposing a portion of the second hard mask layer 118 below the openings 121 as illustrated in FIG. 10. The openings 121 may be any geometric shape, such as a polygon, an ellipsis, and a circle, or the like. In some embodiments, the openings 121 may have a largest dimension Dx along the X axis and have a largest dimension Dy along the Y axis. The short axis of the active areas 102 may have a width Yb. The active areas are arranged in arrays. A width Ya is a distant including the width of the short axis of the active area 102 and the double minimum spacing between the adjacent arrays. The adjacent first dielectric layer 114 may have a longest distant Xa and a shortest distant Xb along the X axis. The dimension Dx may be in a range from about Xa−5 nm to about Xb+5 nm. The dimension Dy may be in a range from about Ya−5 nm to about Yb+5 nm.

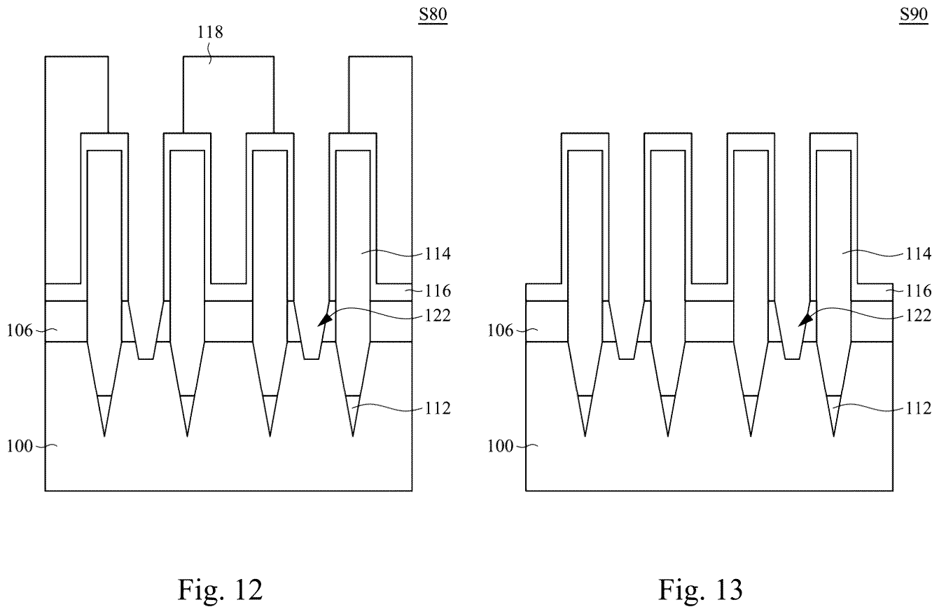

Refer to FIG. 12. FIG. 12 is a cross-section view of a stage of the method of forming the semiconductor structure according to some embodiments of the present disclosure, in which the cross-section of FIG. 12 is taken as the plane A-A shown in FIG. 10. The method goes to step S80. A plurality of the bit line contact holes 122 are formed between the first dielectric layers 114. The plurality of the bit line contact holes 122 extend downward from the top surface of the second dielectric layer 116 through the isolation layer 106 to expose the active area 102 (not shown) of the substrate 100. The bottom surface of the bit line contact holes 122 may be lower than the top surface of the substrate about 40 nm to the about 100 nm. In other words, the substrate may be consumed about 40 nm to 100 nm. The plurality of the bit line contact holes 122 connect a plurality of the bit line structures following formed to the active area 102 of the substrate 100.

First, a first etching operation is performed to remove a portion of the second hard mask layer 118 below the openings 121, exposing a portion of the second dielectric layer 116. The first photoresist 120 may be considered as a block layer which protects the portion of the second hard mask layer 118 below the first photoresist 120 without being consumed during the first etching operation. Then, a second etching operation is performed to remove bottom portion of the second dielectric layer 116, and open the isolation layer 106 to expose the active areas 102 of the substrate 100. The remained second dielectric layer 116 is on the top surface and the side walls of the first dielectric layer 114.

In some embodiments, the plurality of the bit line contact holes 122 may be formed by any suitable operation, such as RIE, wet etching, plasma etching, ICP etching, or the like. In some embodiments, the substrate 100 may be consumed in a range from about 40 nm to about 100 nm after the formation of the plurality of bit line contact holes 122.

Refer to FIG. 13. FIG. 13 is a cross-section view of a stage of the method of forming the semiconductor structure according to some embodiments of the present disclosure, in which the cross-section of FIG. 13 is taken as the plane A-A shown in FIG. 10. The method goes to step S90. The second hard mask layer 118 is removed. In some embodiments, the removal of the second hard mask layer 118 may include RIE, ICP, wet etching or another suitable etch operation.

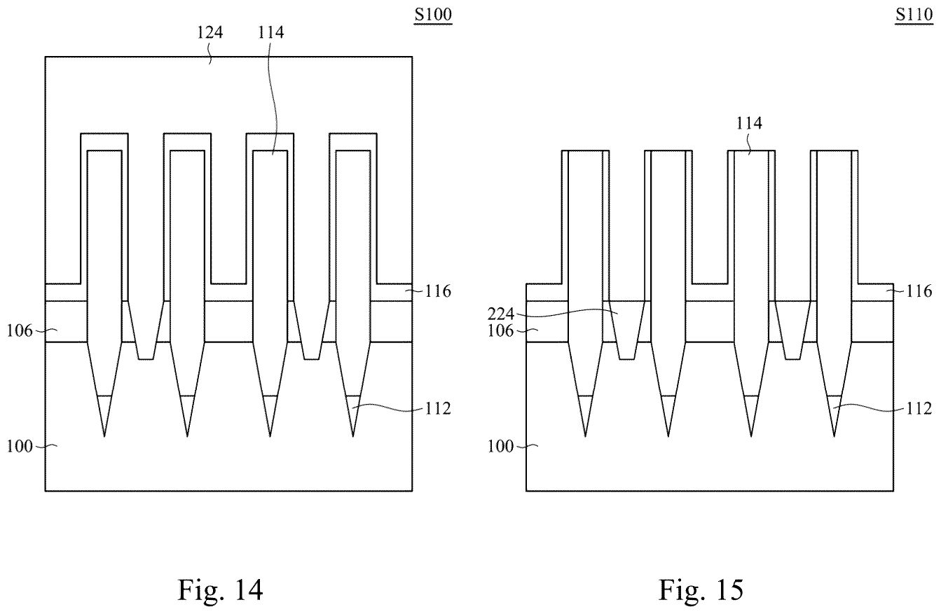

Refer to FIG. 14. FIG. 14 is a cross-section view of a stage of the method of forming the semiconductor structure according to some embodiments of the present disclosure, in which the cross-section of FIG. 14 is taken as the plane A-A shown in FIG. 10. The method goes to step S100. A second conductive layer 124 is formed on the second dielectric layer 116. The second conductive layer 124 is entirely filled into the plurality of the bit line contact holes 122. A material of the second conductive layer 124 can be used by any suitable conductive materials. In some embodiments, the material of the second conductive layer 124 can include tungsten. In some embodiments, the material of the second conductive layer 124 can include polysilicon. The material of the second conductive layer 124 may be deposited by any suitable deposition operation, such as CVD, PVD, ALD, e-beam evaporation, or the like.

Referring to FIG. 15. FIG. 15 is a cross-section view of a stage of the method of forming the semiconductor structure according to some embodiments of the present disclosure, in which the cross-section of FIG. 15 is taken as the plane A-A shown in FIG. 10. The method goes to step S110. A portion of the second conductive layer 124 above the top surface of the isolation layer 106 is removed, leaving remained second conductive layer 124 at the bottom section of the plurality of bit line contact holes 122 (shown in FIG. 13) to form a plurality of bit line contacts 224. In some embodiments, the top surface of the plurality of the bit line contacts 224 and the isolation layer 106 are coplanar. The removal of the second conductive layer 124 may be used CMP, anisotropic etch, combination thereof, or the like. In some embodiments, the second conductive layer 124 may be removed in two steps. First, a top portion of the second conductive layer 124 and the second dielectric layer 116 above the top surface of the first dielectric layer 114 may be removed by CMP. Then remove other portion of the second dielectric layer 116 above the top surface of the isolation layer 106 by any suitable etching operation.

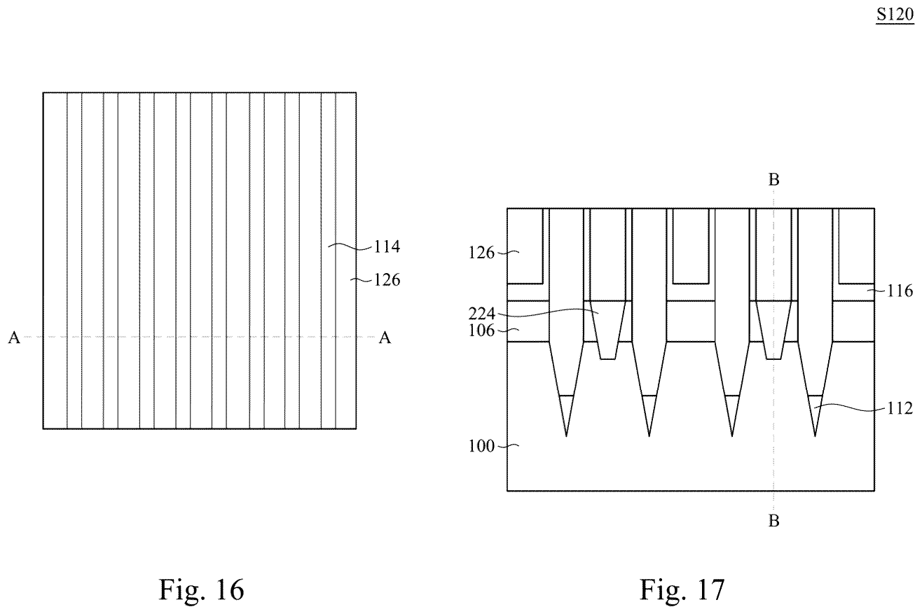

Referring to FIG. 16 and FIG. 17, FIG. 16 is a top view of a stage of the method of forming the semiconductor structure according to some embodiments of the present disclosure, and FIG. 17 is a cross-section view of the semiconductor structure across the plane A-A shown in FIG. 16. The method goes to step S120. A sacrificial layer 126 is formed on the second dielectric layer 116. The sacrificial layer 126 overlies the plurality of the bit line contacts 224 and entirely fills the rest of the plurality of the bit line contact holes 122 (as shown in FIG. 13). After the formation of the sacrificial layer 126, perform a removal operation to remove the sacrificial layer 126 on top surface of the first dielectric layer 114. In some embodiments, the top surface of the first dielectric layer 114, the second dielectric layer 116 and the sacrificial layer 126 are coplanar. The removal of the sacrificial layer 126 may be used CMP, anisotropic etch, combination thereof, or the like. The formation of the sacrificial layer 126 may be deposited by any suitable deposition operation, such as CVD, PVD, ALD, e-beam evaporation, or the like.

The top view of the semiconductor structure of the embodiment is shown in FIG. 16. The first dielectric layer 114 and the sacrificial layer 126 may be disposed apart from each other along the plane vertical to the plane A-A.

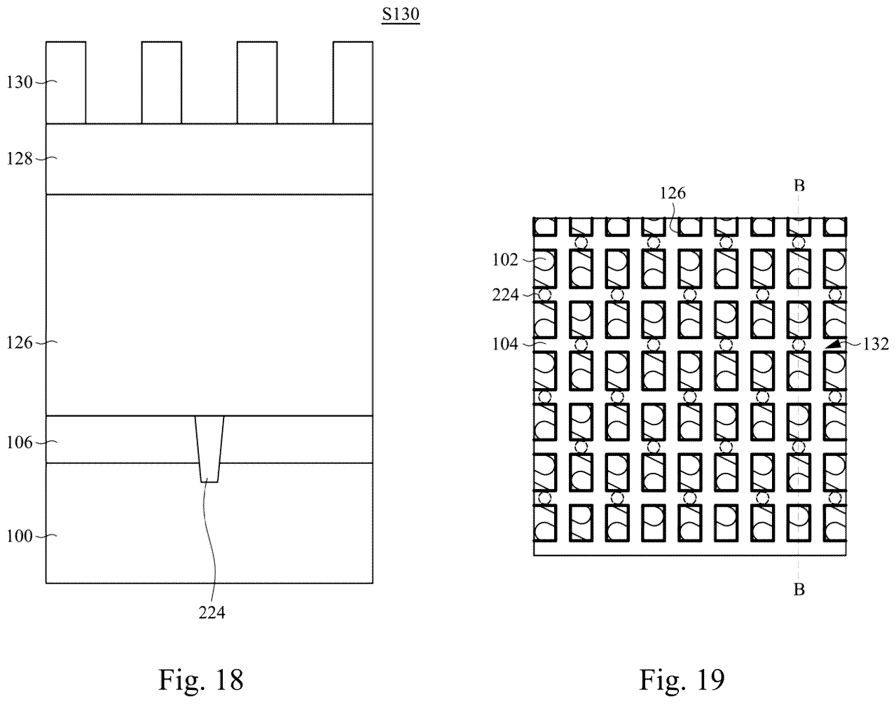

Refer to FIG. 18. FIG. 18 is a cross-section view of a stage of the method of forming the semiconductor structure according to some embodiments of the present disclosure, in which the cross-section of FIG. 18 is taken as the plane B-B shown in FIG. 17. The method goes to step S130. A third hard mask layer 128 is formed on the sacrificial layer 126, followed by the formation of a second photoresist layer. The second photoresist layer may be patterned to form the patterned second photoresist 130.

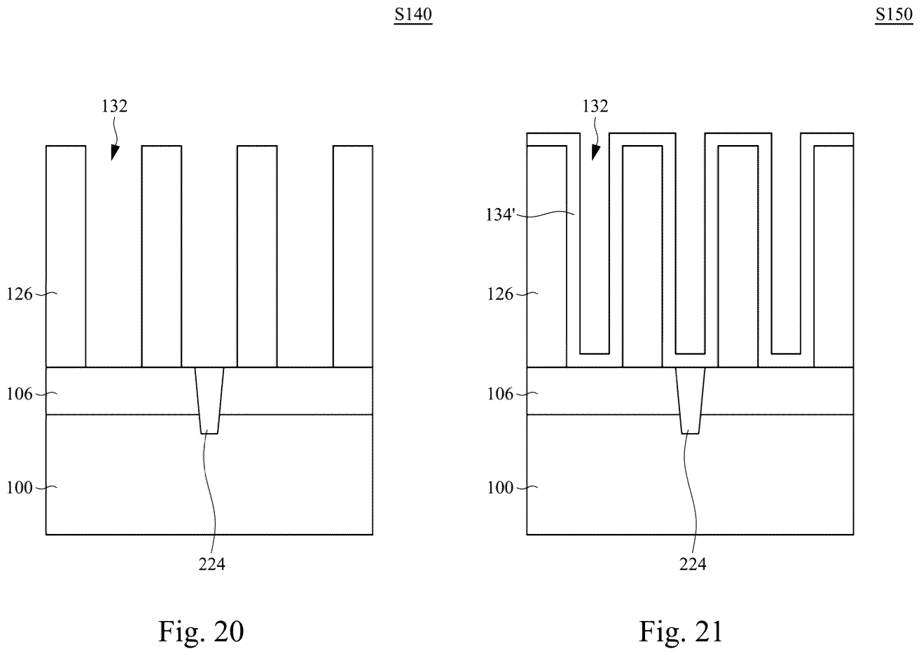

Referring to FIG. 19 and FIG. 20, FIG. 19 is a top view of a stage of the method of forming the semiconductor structure according to some embodiments of the present disclosure, and FIG. 20 is a cross-section view of the semiconductor structure across the plane B-B shown in FIG. 19. The method goes to step S140. A plurality of bit line trenches 132 are formed in the sacrificial layer 126, exposing the plurality of the bit line contacts 224 and a portion of the isolation layer 106, so that the plurality of the bit line contacts 224 may connect to a plurality of the bit lines structures following formed. The formation of the plurality of the bit line trenches 132 may be patterned by any suitable etch operations.

The top view of the semiconductor structure of the embodiments is shown in FIG. 19. The plurality of the bit line trenches 132 extend along the plane vertical to the plane B-B across the plurality of the first dielectric layer 114 and connect to the plurality of the bit line contacts.

Referring to FIG. 21, FIG. 21 is a cross-section view of a stage of the method of forming the semiconductor structure according to some embodiments of the present disclosure, in which the cross-section of FIG. 21 is taken as the plane B-B shown in FIG. 19. The method goes to step S150. A spacer layer 134′ is formed on the sacrificial layer 126 and in the plurality of the bit line trench 132. The spacer layer 134′ may be conformally deposited in the plurality of the bit line trenches 132 as well as on the first dielectric layer (not shown), the sacrificial layer 126 and the bit line contacts 224 and a portion of the isolation layer 106. In some embodiments, the spacer layer 134′ may be deposited by a suitable deposition operation, such as a CVD, LPCVD, PECVD, ALD, PVD, MBE or the like. The material of the spacer layer 134′ may include insulating materials, such as silicon oxide, silicon nitride, silicon oxynitride, silicon carbonitride, silicon oxycarbide, silicon oxycarbonitride, a low-k material, and a combination thereof.

The plurality of the bit line structures (not shown) may be formed reversely. First, the spacer is formed on side walls of the plurality of the bit line trenches, then a conductive material and a dielectric material are formed in the plurality of the bit line trenches.

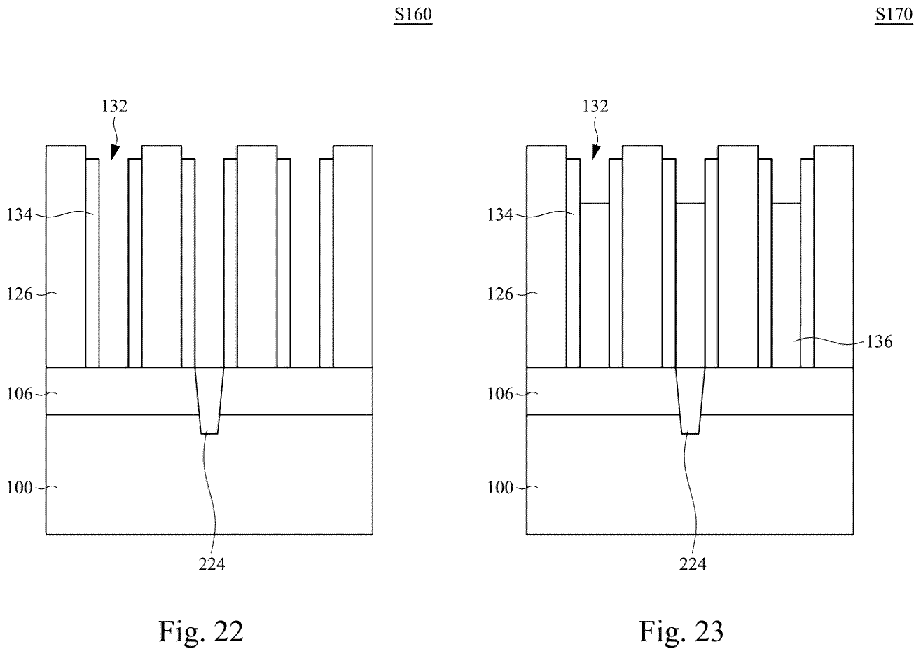

Referring to FIG. 22, FIG. 22 is a cross-section view of a stage of the method of forming the semiconductor structure according to some embodiments of the present disclosure, in which the cross-section of FIG. 22 is taken as the plane B-B shown in FIG. 19. The method goes to step S160. A portion of the spacer layer 134′ is removed on the top surface of the first dielectric layer (not shown) and the sacrificial layer 126 and the bottom surface of the plurality of the bit line trenches 132, exposing the top portion of the bit line contacts 224, and the remained portions of the spacer layer 134′ are spacers 134 on the side walls of the bit line trenches 132. In some embodiment, the top surface of the spacers 134 is lower than the top surface of the sacrificial layer 126. For example, a difference between the top surface of the sacrificial layer 126 and the spacers 134 is about 20 nm. In some embodiments, the removal of the spacer layer 134′ may include RIE, ICP, wet etching or another suitable etch operation.

Referring to FIG. 23, FIG. 23 is a cross-section view of a stage of the method of forming the semiconductor structure according to some embodiments of the present disclosure, in which the cross-section of FIG. 23 is taken as the plane B-B shown in FIG. 19. The method goes to step S170. A third conductive layer 136 is formed in the plurality of the bit line trenches 132. The third conductive layer 136 connects the plurality of the bit line contact 224. The third conductive layer 136 may be formed by depositing conductive material in the plurality of the bit line trenches 132, and removing a top portion of the conductive material on a top surface of the sacrificial layer 126 and the first dielectric layer 114 and in top sections of the plurality of the bit line trenches 132. In some embodiments, the top surface of the third conductive layer 136 is lower than the top surface of the sacrificial layer 126 and the spacers 134.

In some embodiments, the third conductive layer 136 may be a single layer, or double layers, or multilayer. The material of the third conductive layer 136 may be any suitable conductive materials, such as copper, aluminum, nickel, titanium, titanium nitride, tantalum, tantalum nitride, polysilicon, tungsten, cobalt, alloys thereof, or the like. For example, the third conductive layer 136 including polysilicon and tungsten on the polysilicon as a double layer. The material of the third conductive layers 136 may be deposited by other suitable operations, like CVD, ALD, PVD or the like. The removal of the third conductive layer 136 may include any suitable operation, such as reactive ion etching (RIE), wet etching, plasma etching, inductively coupled plasma (ICP) etching, or the like.

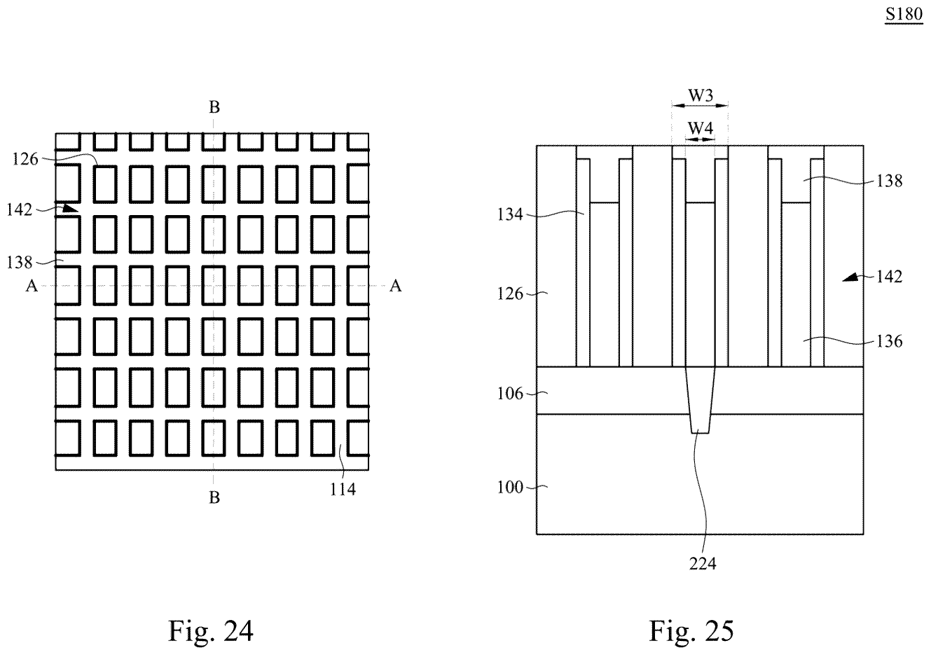

Referring to FIG. 24 and FIG. 25, FIG. 24 is a top view of a stage of the method of forming the semiconductor structure according to some embodiments of the present disclosure, and FIG. 25 is a cross-section view of the semiconductor structure across the plane B-B shown in FIG. 24. The method goes to step S180. The third dielectric layer 138 is formed on the spacers 134 and the third conductive layer 136. The third dielectric layer 138 is formed by depositing a dielectric material on the first dielectric layer (not shown), the sacrificial layer 126, the spacers 134 and the third conductive layer 136, further filling the rest of the bit line trenches 132 (shown in FIG. 23). Then, a top portion of the dielectric material above the sacrificial layer 126 and the first dielectric layer 114 (not shown) is removed to form the third dielectric layer 138. The spacers 134 are entirely covered by the third dielectric layer 138. In some embodiments, the cross section view of the third dielectric layer 138 across the plane B-B may have a T shape. The top surface of the spacers 134 is lower than the sacrificial layer 126, inducing the top portion of the third dielectric layer 138 overlying on the spacers 134. In other words, the width W4 of the bottom portion of the third dielectric layer 138 may be less than the width W3 of the top portion of the third dielectric layer 138. In some embodiments, the top surface of the third dielectric layer 138 and the sacrificial layer 126 are coplanar. The removal of the third dielectric layer 138 may be used any suitable operation, such as CMP, anisotropic etch, combination thereof, or the like.

The top view of the semiconductor structure is shown in FIG. 24. The first dielectric layer 114 and the third dielectric layer 138 are vertical to each other. In other words, the bit line structures 142 are vertical to the first dielectric layer 114. The first dielectric layer 114 extends parallel to the plane B-B, and the third dielectric layer 138 extends parallel to the plane A-A. The sacrificial layer 126 is defined by adjacent the first dielectric layer 114 and the third dielectric layer 138 in a shape such as square, rectangular, or the like. In other words, the sacrificial layer 126 is defined by adjacent the first dielectric layer 114 and the bit line structures 142.

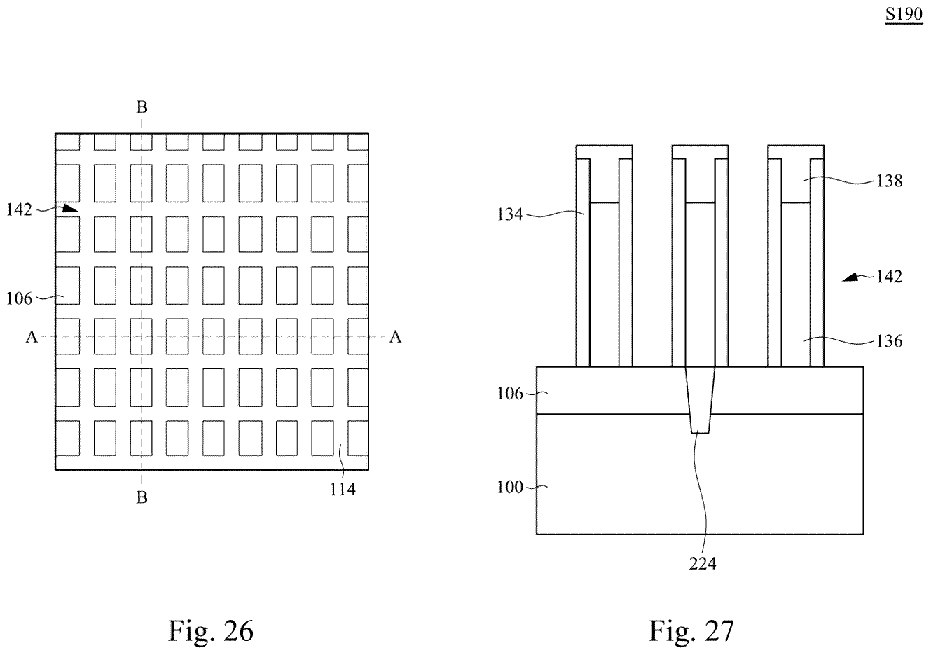

Referring to FIG. 26 and FIG. 27, FIG. 26 is a top view of a stage of the method of forming the semiconductor structure according to some embodiments of the present disclosure, and FIG. 27 is a cross-section view of the semiconductor structure across the plane B-B shown in FIG. 26. The method goes to step S190. The sacrificial layer 126 is removed, exposing the isolation layer 106. After removal of the sacrificial layer 126, the plurality of bit line structures 142 and the first dielectric layer 114 respectively along the plane parallel to the plane A-A and the plane parallel to the plane B-B extend upward from the substrate, in accordance with FIG. 26. In some embodiments, the removal of the sacrificial layer 126 may use RIE, ICP, wet etching or another suitable etch operation.

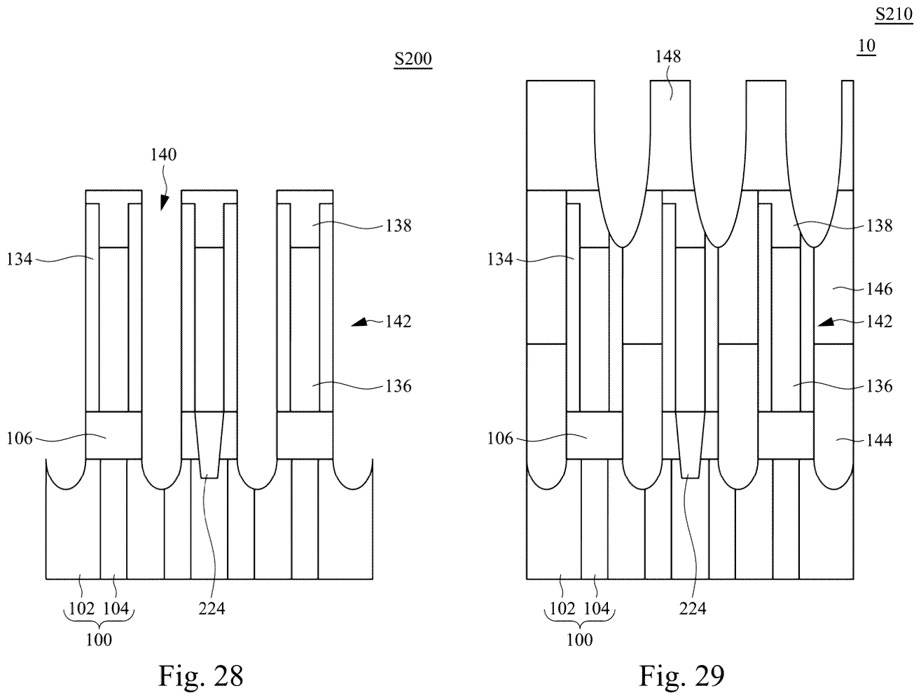

Refer to FIG. 28. FIG. 28 is a cross-section view of a stage of the method of forming the semiconductor structure according to some embodiments of the present disclosure, in which the cross-section of FIG. 28 is taken as the plane B-B shown in FIG. 26. The method goes to step S200. A plurality of capacitor contact holes 140 is formed between bit line structures 142. The plurality of capacitor contact holes 140 may extend through the isolation layer 106 and expose the active area 102 of the substrate 100. The bottom surface of the capacitor contact holes 140 may be lower than the bottom surface of the isolation layer 106. The bottom section of the capacitor contact holes 140 in the substrate 100 may be concave shape. In some embodiments, the removal of the portion of the isolation layer 106 may be an anisotropic etch, such as an RIE or ICP, or punch, or the like.

Refer to FIG. 29. FIG. 29 is a cross-section view of a stage of the method of forming the semiconductor structure according to some embodiments of the present disclosure, in which the cross-section of FIG. 29 is taken as the plane B-B shown in FIG. 26. The method goes to step S210. A plurality of capacitor contacts 144 is formed in the bottom section of the plurality of the capacitor contact holes 140, followed by deposition of a first landing pad 146 and a second landing pad 148. In some embodiments, the plurality of the capacitor contact holes 140 are defined by the first dielectric layer 114 (not shown) and the bit line structures 142. In some embodiments, a silicide process which reduces the contact resistance may be performed prior to the formation of the capacitor contacts 144. The capacitor contacts 144 may be formed by depositing conductive material in the plurality of the capacitor contact holes 140 as well as on the bit line structures 142. Then, the top portion of the conductive material above the top surface of the bit line structures 142 and the top section of capacitor contact holes 140 is removed to form the capacitor contacts 144. The capacitor contacts 144 may connect the capacitors (not shown) to the active area 102 of the substrate 100. The material of the capacitor contacts 144 may be use any conductive material like tungsten, copper, ruthenium, Iridium, Nickel, aluminum cobalt, the alloy thereof, the silicon, the polysilicon, or the like. In some embodiments, the capacitor contacts 144 may be single layer, double layers, or multi layers. The capacitor contacts 144 may be double layer as polysilicon layer and a cobalt layer on the polysilicon layer. The deposition may include CVD, ALD, PVD, flowable chemical vapor deposition (FCVD), LPCVD or other suitable operations. The removal may include RIE, ICP, wet etching or another suitable etch operation.

After formation of the capacitor contacts 144, the first landing pad 146 is formed on the capacitor contacts 144. The first landing pad 146 is formed by depositing a conductive material on the bit line structure 142 and filling the rest of the capacitor contact holes 140. A top portion of the conductive material above the top surface of the plurality of the bit line structures 142 may be removed to form the first landing pad 146. In some embodiments, the top surface of the plurality of the bit line structures 142 and the first landing pad 146 are coplanar. The removal of the top portion of the first landing pad 146 may include CMP, anisotropic etch, combination thereof, or the like. After formation of the first landing pad 146, the second landing pad 148 is formed on the first landing pad 146. A conductive material is deposited, followed by patterning the conductive material to form the second landing pad 148. The second landing pad 148 overlies a top portion of the bit line structures 142. The material of the first landing pad 146 and the second landing pad 148 may include one or more metal conductive materials, such as aluminum, copper, tungsten, titanium (Ti), tantalum (Ta), titanium aluminum alloy (TiAl), titanium aluminum nitride (TiAIN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru), titanium silicon nitride (TiSiN), other suitable materials, or a combination thereof.

The semiconductor structure 10 formed by the method of forming the semiconductor structure is provided in FIG. 29. The semiconductor structure 10 includes the substrate 100, which includes the active area 102 and the isolation area 104 spacing apart from the active area 102. The isolation layer 106 is disposed on the top surface of the active area 102 and the isolation area 104. The plurality of bit line structures 142 may be disposed apart from each other on the isolation layer 106. The plurality of the bit line structures 142 include the third conductive layer 136, the third dielectric layer 138 on the third conductive layer 136, and the spacers 134 on the side walls of the third dielectric layer 138 and the third conductive layer 136. The plurality of the bit line contacts 224 are disposed below a portion of the bit line structures 142 through the isolation layer 106. In addition, the bit line contacts 224 connects the bit line structures 142 to the active area 102 of the substrate 100. The plurality of the capacitor contacts 144 are disposed between the bit line structures 142 and connect the capacitor (not shown) to the active area 102 of the substrate 100. The first landing pad 146 and the second landing pad 148 are formed in sequence on the capacitor contacts 144.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of forming a semiconductor structures, comprising:
forming a hard mask layer on a substrate;
forming a plurality of word line trenches in the substrate and the hard mask layer;
forming a plurality of word line structures in the word line trenches, wherein a top surface of the word line structures is coplanar with a top surface of the substrate;
forming a first dielectric layer in the word line trenches and extending upward from the substrate, wherein a top surface of the first dielectric layer is coplanar with a top surface of the hard mask layer;
removing the hard mask layer to define a plurality of trenches in the first dielectric layer;
forming a sacrificial layer in the trenches;
forming a plurality of bit line trenches in the sacrificial layer and the first dielectric layer; and
forming a plurality of bit line structure in the bit line trenches.

2. The method of claim 1, wherein the forming a plurality of bit line structure in the bit line trenches comprising:
forming spacers on side walls of the bit line trenches;
forming a conductive layer in the bit line trenches; and
forming a second dielectric layer on the conductive layer.

3. The method of claim 2, wherein the forming the spacers on side walls of the bit line trenches comprising:
depositing a spacer layer on the sacrificial layer; and
etching a top portion of the spacer layer.

4. The method of claim 3, wherein a top surface of the spacer is lower than a top surface of the sacrificial layer.

5. The method of claim 4, wherein a difference between the top surface of the spacer and the sacrificial layer is about 20 nm.

6. The method of claim 2, wherein the forming the conductive layer in the bit line trenches comprising:
depositing a conductive material in the bit line trenches; and
etching a top portion of the conductive material.

7. The method of claim 6, wherein a top surface of the conductive layer is lower than a top surface of the spacers.

8. The method of claim 2, wherein the forming the second dielectric layer comprising:
depositing a second dielectric material on the conductive layer and the spacers; and
removing a top portion of the second dielectric material.

9. The method of claim 8, wherein a top surface of the second dielectric material is coplanar with a top surface of the sacrificial layer.

10. The method of claim 8, wherein a top portion of the second dielectric layer on the spacers has a first width and a bottom portion of the second dielectric layer adjacent the spacers has a second width less than the first width.

11. The method of claim 10, wherein the second dielectric layer has a T shape in cross section view.

12. A method of forming a semiconductor structures, comprising:
forming a plurality of word line structures in a substrate;
forming a first dielectric layer on the substrate, wherein the first dielectric layer vertical aligns with the word line structures;
depositing a sacrificial layer on the substrate;
forming a plurality of bit line structures in the sacrificial layer, wherein the first dielectric layer extends in a first direction, and the bit line structures extend in a second direction vertical to the first direction;
removing the sacrificial layer; and
forming a plurality of capacitor contacts on the substrate, wherein locations of capacitor contacts defined by the first dielectric layer and the bit line structures.

13. The method of claim 12, wherein forming a plurality of bit line contacts between the word line structures is prior to the forming the sacrificial layer on the substrate.

14. The method of claim 13, wherein the forming the plurality of bit line contacts between the word line structures comprising:
forming a second dielectric layer on the first dielectric layer;
forming a plurality of bit line contact holes between the first dielectric layer and the second dielectric layer;
forming a conductive material in the bit line contact holes; and
etching a top portion of the conductive material.

15. The method of claim 14, wherein the second dielectric layer defines a dimension of the bit line contacts.

16. The method of claim 12, wherein side walls of the word line structures vertical aligns with side walls of the first dielectric layer.

17. The method of claim 12, wherein forming the capacitor contacts comprising:
forming a plurality of capacitor contact holes between the bit line structures;
depositing a conductive layer in the capacitor contact holes; and
etching a top portion of the conductive layer.

18. The method of claim 17, wherein a bottom of the capacitor contact holes is lower than a top surface of the substrate about 40 nm.

19. The method of claim 12, wherein the method further comprising:
forming a first landing pad on the capacitor contacts; and
forming a second landing pad on the first landing pad, wherein the second landing pad overlies on a portion of a top surface of the bit line structures.

20. The method of claim 19, wherein the forming a first landing pad on the capacitor contacts comprising:
forming a conductive material on the capacitor contacts; and
removing a top portion of the conductive material, wherein
a top surface of the first landing pad is coplanar with a top surface of the bit line structures.
